(19) United States
(12) Patent Application Publication
(10) Pub. No.: US 2025/0329510 A1
(43) Pub. Date: Oct. 23, 2025

(54) SEMICONDUCTOR ELECTRODE STRUCTURES AND METHODS OF FORMING SAME

(71) Applicant: Taiwan Semiconductor Manufacturing Company, Ltd., Hsinchu (TW)

(72) Inventors: Yun-Chung Wu, Taipei (TW); Fu Wei Liu, Tainan (TW); Chia-Ai Chiu, Kaohsiung (TW); Szu-Hsien Lee, Tainan (TW); Pei-Wei Lee

(21) Appl. No.: 18/638,088

(22) Filed: Apr. 17, 2024

(51) Int. Cl. H01J 37/28; H01L 21/28; H01L 21/311

(52) U.S. Cl. CPC H01J 37/28; H01L 21/28079; H01L 21/28123; H01L 21/31138; H01J 2893/0002

(57) ABSTRACT

Forming an electrode structure includes forming a first cavity and a second cavity in a first hard mask layer, filling the first cavity and the second cavity with an electrically conductive material to form a first electrically conductive pillar and a second electrically conductive pillar; and planarizing exposed surfaces of the first and second electrically conductive pillars. Thereafter, a second hard mask layer is disposed on the first hard mask layer, a third cavity is formed passing through the second hard mask layer, and a second electroplating and planarization process fills the third cavity with the electrically conductive material to form a third electrically conductive pillar contacting the second electrically conductive pillar. A first electrode comprises the first electrically conductive pillar, and a second electrode comprises a combination of the second and third electrically conductive pillars.

### BACKGROUND

The following relates to semiconductor devices, to semiconductor electrode structures and methods of forming same, micro-electromechanical system (MEMS) devices, and to multiple electron beam steering devices, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A-1C illustrate an example method of forming an electrode structure for comparison with an example method of forming an electrode structure according to an example embodiment of this disclosure.

FIG. 2 illustrates an operation of an electrode structure used for e-beam steering according to an example embodiment of the present disclosure.

FIG. 3 illustrates an example electrode structure formed with a method using multiple patternable hard mask layers according to an example embodiment of the present disclosure.

FIGS. 4A-4G illustrate various stages in the formation of an electrode structure according to example embodiments of the present disclosure.

FIG. 5 is a detailed illustration of an electrode structure according to an example embodiment of the present disclosure.

FIG. 6 is another detailed illustration of an electrode structure according to an example embodiment of the present disclosure.

FIGS. 7A-7D illustrates a hard mask layer stacking method of forming an electrode structure according to example embodiments of the present disclosure.

FIG. 8 is a flow chart of a method of forming an electrode structure according to example embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “layer”, as used herein, may include a single layers or multiple layers.

The term “intermetal dielectric” (IMD) film or layer, as used herein, refers to a dielectric/insulation material(s) layer between two metal layers.

The term “interlayer dielectric” (ILD) layer, as used herein, refers to an insulating structure of material(s) placed between two conductive layers.

Use of the term “hybrid”, as used herein, relates to electrode height structure (hybrid electrode height) refers to more than one electrode, where the electrodes have pillars of different lengths and/or heights, or where one electrode is taller than the other electrode.

The term “TME”, as used herein, refers to a metallization layer and/or top metallization layer.

The term “TSV”, as used herein, refers to a through silicon via or through via which can also be though another material such as a dielectric material or layer, e.g. SiO2.

The term “MEMS”, as used herein, refers to micro-electromechanical systems and devices that include systems and devices that incorporate both electronic and moving parts or incorporate both electronic and mechanical devices and/or structures, such as electrodes structures, without moving parts, integrated with an electronic driver circuit, such as a transistor.

The term “tiered” or “multitiered” structure, as used herein, refers to a structure which includes multiple levels or layers, where each successive level or layer is narrower in width than the preceding level or layer.

The term “metal electroplating” as used herein refers to the electroplating of metals or other electrically conductive materials

Electrodes, and electrode structures, are used in a variety of devices, including e-beam (electron beam) steering devices, such those used in e-beam or multibeam writer tools for semiconductor mask and wafer writing, and e-beam inspection tools used for a variety of applications. For example, electrode structures including conductive pillars, i.e. electrodes, of different lengths are formed on a driving circuit, such as a silicon wafer with CMOS devices, to function as an electron beams control device, an electron multibeam deflection plate for an electron mask exposure tool, e-beam lithography tool, or the like used for semiconductor fabrication. The integration of the electrode structure and the driving circuit, i.e. CMOS device or structure, is at times referred to as a mask writer MEMS device or electrode MEMS device within this disclosure.

As will be further described herein, the function of the electrodes within the context of e-beam steering is to electrostatically deflect or control (i.e., effectively turn off) an electron beam (or beamlet) passing through an electron beam pass-through of the electron beams control device by way of the electrically charged field applied by an electrically biased electrode and a reference (e.g., ground) electrode.

This disclosure, and the example embodiments described herein, provides an electrode structure, and method of forming the same, and also a MEMS structure including the electrode structure and driving circuit, for use as a beamlet steering plate of an e-beam mask writer, e-beam lithography tool, or the like. However, it is to be understood that the electrode structures and methods disclosed herein are not limited to these applications. Other applications of the disclosed electrode structures and methods include e-beam inspection tools, etc.

As disclosed herein, the electrode structure includes a pair of electrodes of different lengths. The different lengths of the electrodes provides for the use of the electrode structure with suppression or elimination of interference between the steered electron beams, where one electrode is for grounding and the other electrode acts as a switch for electron beams control.

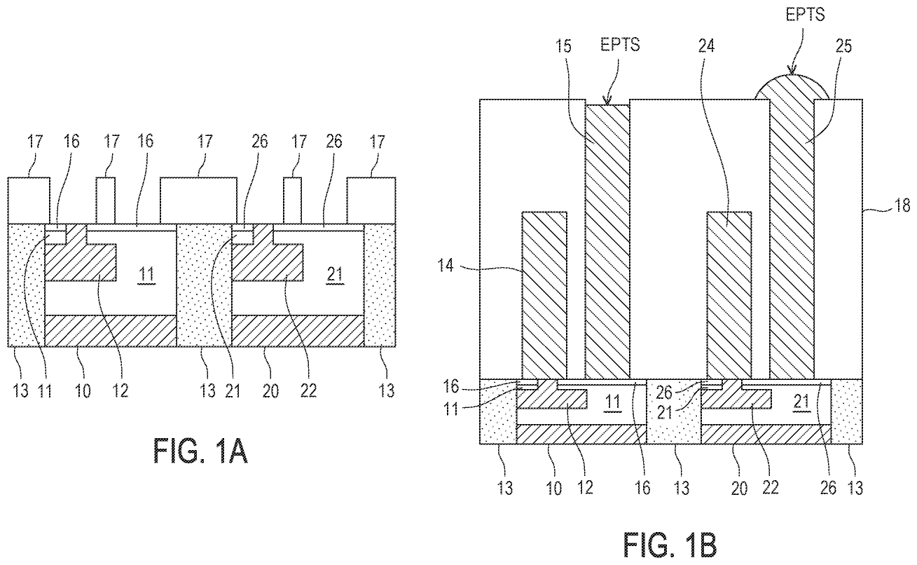

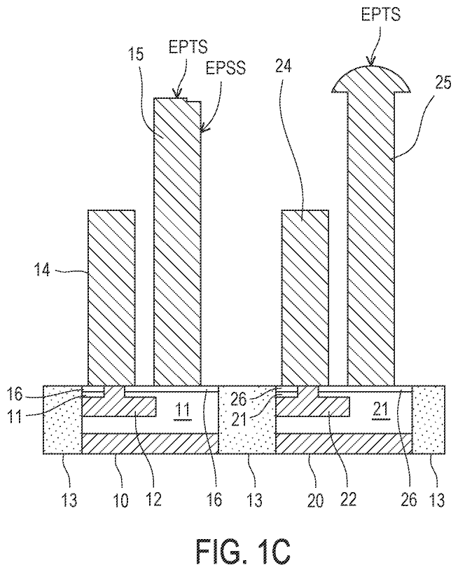

One method of forming a hybrid height electrode structure includes the use of a multiple photoresist patterning and metal electroplating processes to form the electrode structure on a driving circuit. The driving circuit is suitably formed as a wafer or die including, in part, a CMOS transistor, dielectric layers, and a top patterned metallization layer (TME) which includes electrical contacts for electrically bonding the electrode structure during the PR (photoresist) patterning and metal electroplating process. As will be described further with reference to FIGS. 1A-1D below, the PR patterning and metal electroplating process includes a series of steps including: 1) performing a coating process to apply a PR coating to the driver circuit surface including the TME; 2) performing an exposure process to expose the PR coating to create a PR pattern for subsequent development; 3) developing the patterned and exposed PR resist coating to remove the patterned PR and expose the regions of the top surface of the CMOS device for subsequent metal electroplating; and 4) metal electroplating a first metal layer of both the electrodes for the electrode structure. Process steps 1)-4) are repeated to fabricate the electrodes, where each iteration of the coating, exposure, developing, and metal electroplating process steps extends the height of the electrodes. After the electrodes have been fabricated to the design-basis height, the PR is removed to expose the electrodes.

The PR resolution achieved by PR photo processing can limit the achievable aspect ratios for electrode formation. Furthermore, the PR patterning and metal electroplating processes produce jagged and nonuniform electrode side wall profiles because of the multi-PR patterning and metal electroplating process. In other words, the standard deviation of the width of pillars/electrodes can be relatively high. The jagged or nonuniform sidewall can create substantial nonuniformity in the electrostatic field generated between the biased and ground pillar electrodes, which in turn can adversely impact controllability of the electron beamlet steering. Furthermore, the multi-PR patterning and metal electroplating process for MEMS devices with high aspect ratio electroplated metal electrodes can result in over-plating of the metal material on the top of the electrode (mushroom) or under-plating (hump or dimple), due to loading effect. This mushroom or under-plating can also adversely impact uniformity of the steering electrostatic field, and can contribute to interference between the steering of neighboring electron beams.

Provided and described herein, is another hybrid height electrode structure, and method of forming the same, that includes the metal electroplating of multiple layers, or stacks or tiers, of conductive pillars to form the electrode structure, where the taller electrode includes a top section of conductive pillar that has a width that is narrower than the width of the bottom section of conductive pillar below the top conductive pillar section. The disclosed approach is similar to a dual-Damascene process, and advantageously facilitates fabrication of high aspect ratio electrodes with different heights (e.g., taller ground electrode and shorter biased electrode) and straight sidewalls. A hard mask layer is formed to the height of the electrode (or a portion thereof) and is patterned to form cavities for the short and tall electrodes, followed by a metal electroplating process and Chemical Mechanical Polishing (CMP) or another planarization process to fill the cavities so as to form the electrode pillars. The hard mask is then removed, e.g., by suitable etching, to expose the high aspect ratio (pillar) electrodes. The result is a hybrid height electrode structure that has electrodes with pillar widths that are uniform throughout the pillar section, and the electrode top surfaces are flat. In other words, the patternable hard mask and metal electroplating processes include a patternable hard mask layer process to define a pattern, and then the process follows a dual damascene like process to create metal electrodes of different heights which have profiles including non-jagged sides/smooth sides and flat top surfaces. The hard mask stacking and deposition/coating/bonding process provides better pillar/electrode profile control relative to the patterned PR and metal electroplating structure and method.

Referencing FIGS. 1A-1C, described now is an electrode structure, and method of forming the same, that uses an iterative photoresist patterning and metal electroplating process to form two sets of electrodes for use as an e-beam steering device. The first set of electrodes including electrodes 14 and 15, and the second set of electrodes including electrodes 24 and 25 (FIG. 1B).

As shown in FIG. 1A, initially the PR hybrid height electrode formation process performs initial PR Coating, Exposing and Developing PR processes to create an initial patterned PR layer 17 on a driver circuit 8 including CMOS devices 10 and 20, IMD/ILD layers 11 and 21, top patterned metallization layers 12 and 21, and optional passivation layers 16 and 26. For an electron beams control device or multibeam deflection plate, the driver circuit 8 is suitably formed as a two-dimensional (2D) array of CMOS devices 10, 20 and associated e-beam pass throughs 13. FIGS. 1A, 1B, and 1C show an illustrative portion of such an array including one electron beam pass-through 13 and two CMOS devices 10, 20.

Notably, the photoresist layer 17 is relatively thin, and in particular is not as thick as the desired final height of the pillar electrodes. The maximum thickness of the photoresist can be limited by the relative softness of the photoresist—attempting to make the photoresist layer 17 too thick and then patterning it can result in photoresist collapse, in which the patterned features are distorted or partially filled. This is particularly likely for closely packed, high aspect ratio features with a small lateral critical dimension.

Next, as shown in FIG. 1B, the PR hybrid height electrode formation process includes performing a metal electroplating process to plate a first metal layer of electrode pillars 14, 15, 24 and 25. Due to the relative thinness of the photoresist layer 17, this results in electrically conductive pillars with heights that are substantially shorter than the desired final electrode height. Thus, to obtain the desired high aspect ratio pillar electrodes, the PR patterning process is repeated multiple times to gradually increase the height of the pillars to form the final electrodes 14, 15, 24 and 25 with a plurality of patterned PR layers 18 and electroplated metal layers, resulting in the structure shown in FIG. 1B. If the patterned openings of the successive photoresist layers are not exactly aligned, this results in jagged sidewalls of the electrodes 14, 15, 24, and 25. The process to reach the structure shown in FIG. 1B is also time-consuming and tedious as it entails multiple iterations of the photoresist layer deposition, patterning, and electroplating steps.

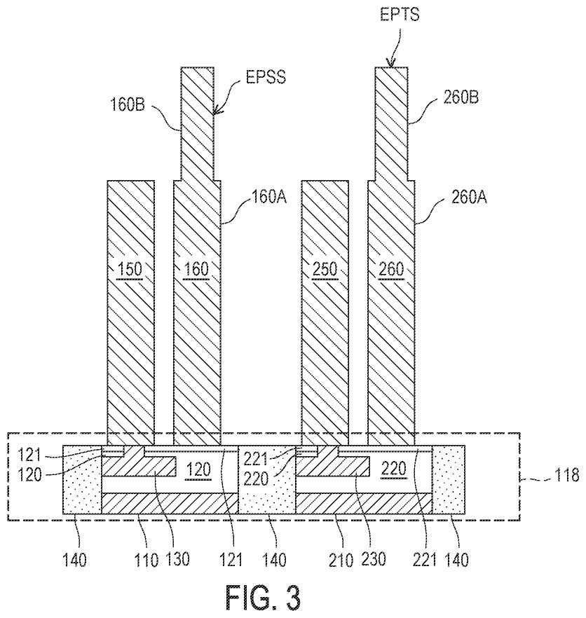

Next, as shown in FIG. 1C, the PR material is removed using a PR material removal process appropriate for the PR layer material. The resulting hybrid electrode height structure is illustrated in FIG. 3C, which is a duplication of the structure shown in FIG. 1B, except the patterned PR layers are removed from the structure. As shown in the electrode pillar top surfaces (EPTS) labeled in FIG. 1C, the top surface of electrode pillar 15 includes an underfilled/dimpled/rough/jagged electrode end surface, and the top surface of electrode 25 includes an overfilled/mushroomed electrode pillar end surface. In addition, the electrode pillar side walls, as referenced by EPSS in FIG. 1C, have a side wall profile which is jagged, i.e. relatively high standard deviation of electrode width. In other words, the patterned PR metal electroplating process results in an electrode structure that includes uneven and inconsistent metal plated surfaces.

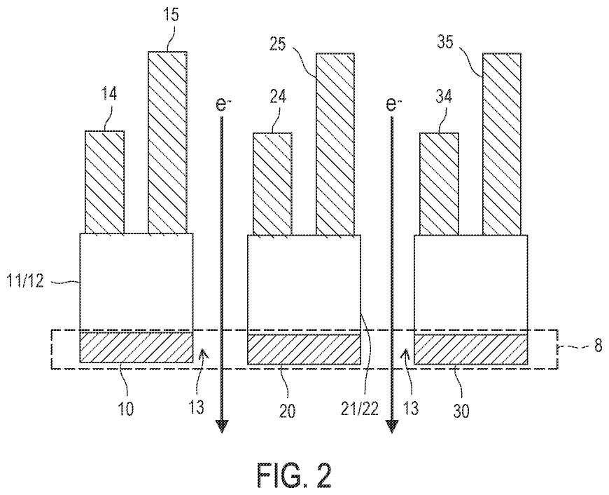

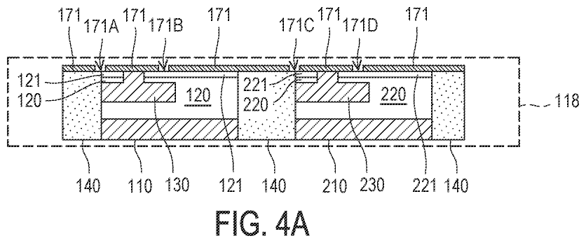

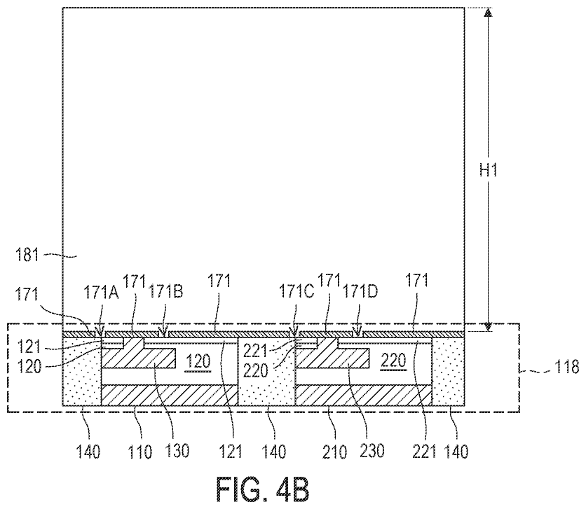

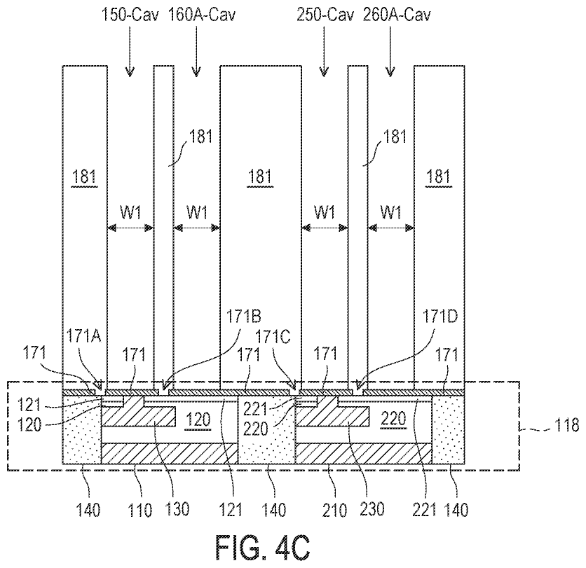

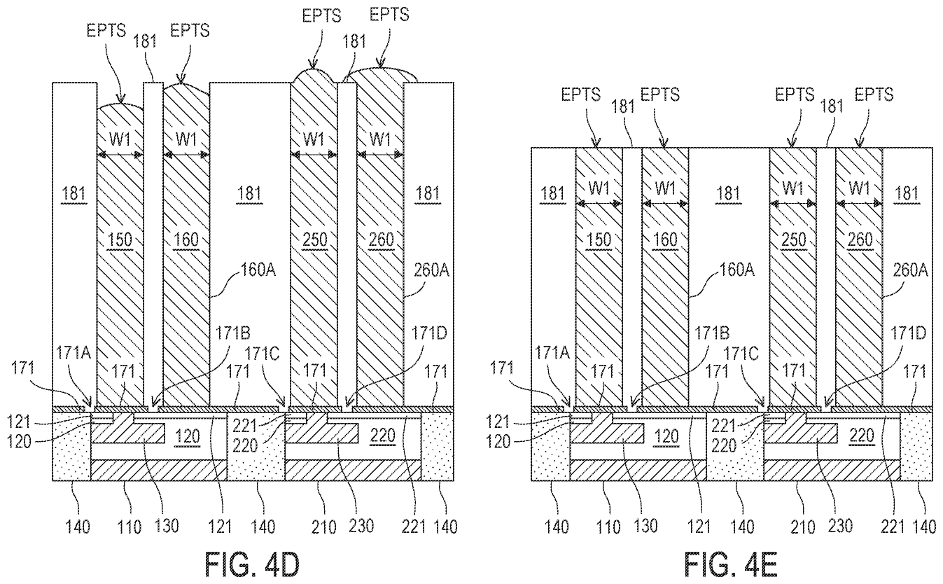

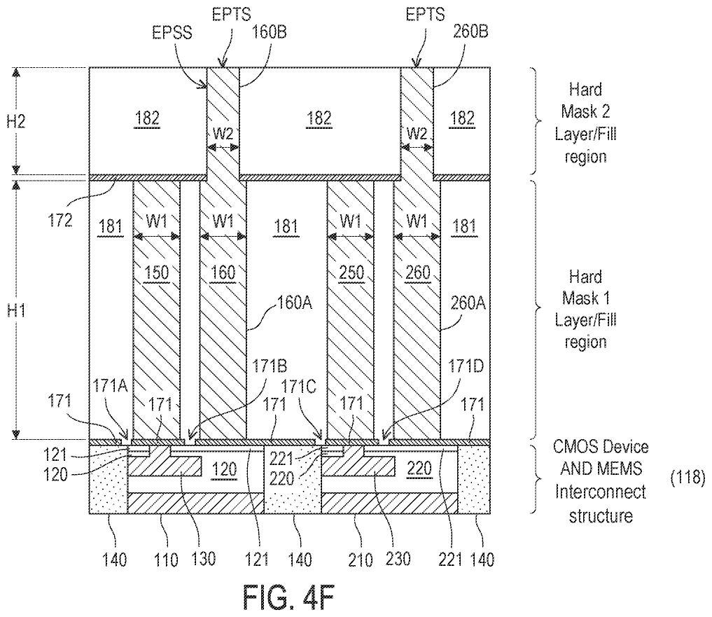

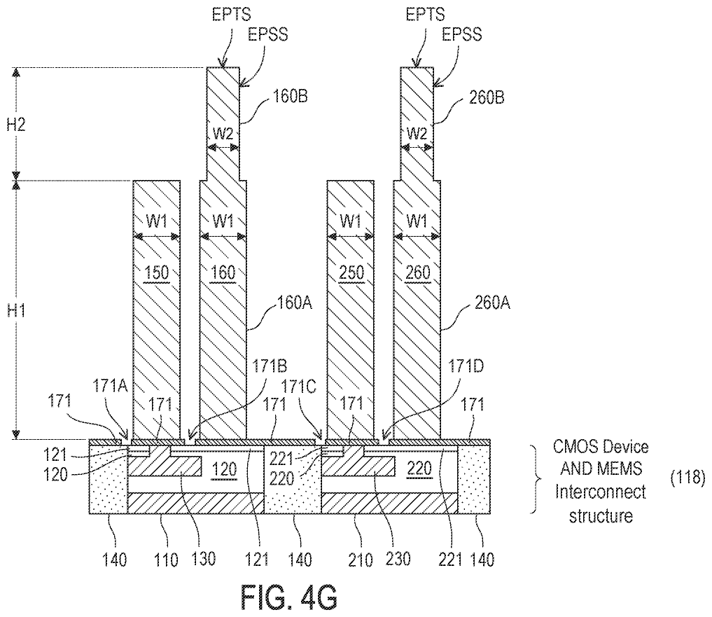

Referencing FIG. 2, while the reference numbers used are associated with the patterned PR formed electrode structure of FIGS. 1A-1C, the operation of the electrode structure as used as an electron beam steering device equally applies to the disclosed electrode structure formed with multiple successively electroplated metal pillars which diminish in width and are formed using a patternable hard mask (e.g., as described herein with reference to FIGS. 3 and 4A-4G).

As shown in FIG. 2, the electron beam steering device structure includes a driver circuit 8 (e.g., including transistors 10 and a patterned metallization layer 11, 12 as previously described) for driving the electrodes 14, 15, 24, 25, 34 and 35. Two beam steering devices are shown in FIG. 2, however, it will be appreciated that for some applications there may be a larger number of beam steering devices, for example forming a two-dimensional array of beam-steering devices for certain applications. In general, by suitable biasing of the electrodes 14, 15, 24, 25, 34, 35 the e-beams (diagrammatically indicated by arrows labeled “e⁻” in FIG. 2) can be steered within the e-beam pass throughs 13, or deflected entirely outside of the e-beam pass throughs 13 (e.g., to turn the e-beam on or off, as may be suitable for some applications).

Referencing FIG. 3 and with comparative reference back to FIG. 1C, provided now is a comparison of a patterned PR and plated hybrid height electrode structure (FIG. 1C) profiles and a hard mask (HM) patterned/tiered and plated hybrid height electrode structure profile (FIG. 3).

As previously described with reference to FIGS. 1A-1C, the resulting electrode structure from the patterned PR and metal electroplating process includes electrodes 14, 15, 24 and 2. As shown in FIG. 1C, the top surface EPTS of electrode 25 includes an overfilled/mushroomed electrode pillar end surface and the electrode pillars, as referenced by EPTS area of FIG. 1C have a side wall profile which is jagged, i.e. a relatively high standard deviation of electrode width. In other words, the patterned PR metal electroplating process results in an electrode structure that includes uneven and inconsistent metal plated surfaces.

In contrast to FIG. 1C, FIG. 3 shows a hard mask (HM) patterned/tiered and plated hybrid height electrode structure as disclosed herein, including electrodes 150, 160 (comprising sub-pillars 160A and 160B), 250, and 260 (comprising sub-pillars 260A and 260B). By using a two-step HM patterning and metal electroplating process, the taller electrodes 160 and 260, each include two tiers of pillars. Electrode 160 includes electrode pillars 160A and 160B, where the width of electrode pillar 160A is W1 and the width of electrode pillar 160B is W2, where W2 is less than W1 thereby providing a tiered electrode structure. Similarly, electrode 260 includes electrode pillars 260A and 260B, where the width of electrode pillar 260A is W1 and the width of electrode pillar 260B is W2, where W2 is less than W1 thereby providing a tiered electrode structure. Through use of post-electroplating planarization, the resulting electrode structure includes a flat electrode top end surface EPTS, without mushrooming/dimples/underfilled regions, and through use of a thick hard mask (or two thick hard masks) the electrode pillars have sidewalls that are relatively smooth and have a consistent width/cross-sectional profile over the length of the electrode pillar (except at the designed abrupt junction between the lower portion 160A/260A and upper portion 160B/260B for the taller pillars 160/260), relative to the patterned PR and metal electroplating process. In other words, straight metal electrodes are formed by using patternable hard mask layer(s) to define a high aspect ratio pattern. A CMP process (applied to the top surface of the HM layer and electrode top end surface prior to removing the HM layers) flatten the electrode top end surfaces surface to achieve a more uniform electrode height (H1+H2) and overall more consistent electrode shape profile.

Similar to the electrode driving circuit previously described, each electrode structure set of FIG. 3 is controlled by a driver circuit 118 including transistors 110 and 210, IMD/IML 120 and 220, patterned metallization layers 130 and 230 which electrically connect to a CMOS device, optional passivation layers 121 and 221, and e-beam pass-throughs/TSVs 140 for an e-beam or multibeam passing between electrodes 160 and 250. PASS openings are provided by the top surfaces of top metalization layer 130 and 230. In this example, the central electron beam pass-through/TSV 140 has reference electrode 160 on one side (i.e., left side), and bias electrode 250 on the opposite side (i.e., right side). During the HM patterning and removal process, isolation structure 171A, 171B, 271A and 271B are provided to electrically isolate electrodes 150 and 160, and electrically isolate electrodes 250 and 260.

Referencing FIGS. 4A-4G, illustrated are various stages in the formation of an electrode structure such as that of FIG. 3, e.g., for an electron beam steering device, according to example embodiments of the present disclosure.

Referencing FIG. 4A, the electrodes fabrication process starts with providing the driver circuit 118, e.g., including the illustrative transistors 110 and 210, e.g. CMOS transistors, IMD/IML layers 120 and 220, patterned metallization layers 130 and 230 made of copper or other conductive metal compounds, passivation layers 121 and 221, and through-holes/TSVs 140. The base material for the driver circuit 118 may be silicon, or a dielectric material such as, but not limited to silicon dioxide, or other material or combination of materials suitable as a substrate for the active transistors and mechanically supportive for depositing the IMD/IML layers 120 and 220. The driver circuit 118 can be fabricated using CMOS integrated circuit (IC) fabrication technology or the like to form the CMOS devices 110, 210 in a silicon wafer or substrate, and back end-of-line (BEOL) processing to form the IMD/IML layers 120, 220 and one or more metallization layers including a the top metal (TME) layer 130.

Referencing FIG. 4B, a first hard mask layer 181 is deposited on the driver circuit 118, e.g., on the top metallization layers 130 and 230, passivation layers 121 and 221, and adhesion layer and metal electroplating contact seed layer 171. According to the example embodiment illustrated, the first hard mask layer 181 thickness or height is H1, the HM layer material is a silicon, dielectric, or polymer material, and the HM material deposition or covering process may include a deposition film, and/or three-dimensional (3D) printing processes. Notably, the first hard mask layer 181 comprises a material which is harder than photoresist. Thus, the first hard mask layer 181 can be made (and subsequently successfully patterned) with a greater thickness than the photoresist layer 17 of a processing iteration of the embodiment of FIGS. 1A-1C. In particular, the height H1 of the first hard mask layer 181 can be equal to the final height of the bias electrodes 150 and 250 (or H1 can be slightly higher to accommodate subsequent CMP planarization), so that the bias electrodes 150 and 250 along with the lower portions 160A/260A of the taller ground electrodes 260 can be made in a single, noniterative process sequence.

Referencing FIG. 4C, the first cavities 150-Cav and 250A-Cav and second cavities 160A-Cav and 260A-Cav are formed in the first hard mask layer 181, for example by a suitable photolithographically controlled etching process. A dry etching process may be used to etch the cavities 150-Cav, 250A-Cav, 160A-Cav, and 260A-Cav with a width of W1 in the first hard mask 181 at locations where a subsequent metal electroplating process fills the cavities with an electrically conductive material to form electrode pillars 150, 160A, 250 and 260A. According to an example embodiment, the dry etching process used is dependent on the HM film material, where different plasma dry etching gases are used to remove the hard mask layer 181 For example, SF6 etching gas is used if the HM layer 181 material is silicon, CF4 etching gas is used if the HM layer 181 material is a dielectric material, and 02 gas is used an etching gas if the HM layer 181 material is a polymer material. The first cavities 150A-Cav and 250A-Cav pass through the first hard mask layer 181 to the patterned metallization layer 130, and likewise the second cavities 160A-Cav and 260A-Cav pass through the first hard mask layer 181 to the patterned metallization layer 181. The first cavities 150A-Cav and 250-Cav will be filled by electroplating to form first electrodes 150 and 250, and the second cavities 160A-Cav and 260A-Cav will be filled by the electroplating to form the lower parts 160A and 260A of the second electrodes 160 and 260, respectively (see FIG. 4D and related discussion). The cross-sectional size and shape of the cavities will thus determine the cross-sectional size and shape of the corresponding electrodes or lower electrode portions. Typically, the cross-sections of the cavities and corresponding electrodes or lower electrode portions will be circular; however, other cross-sectional shapes such as square, rectangular, hexagonal, more generally polygonal, or so forth are alternatively contemplated.

Optionally, prior depositing the first hard mask 181 (as shown in FIG. 4B), the process first covers the top surface of an electrode semiconductor driver circuit 118 with an optional adhesion or protective layer (not shown) and metal electroplating contact seed layer 171. The optional adhesion or protective layer may, for example, protect the wall of the via opening 56 during the copper electroplating process, a thin layer 60 of a protective material such as tantalum (Ta), tantalum nitride (TaN), silicon nitride (SiN), silicon carbide (SiC), or so forth may optionally be applied to the wall of the via opening 56 before performing the copper electroplating The seed layer 171 is typically a thin layer of the same material to be electroplated (e.g., a copper seed layer for copper electroplating), with the seed layer being deposited by a physical vapor deposition (PVD), chemical vapor deposition (CVD), or the like.

The metal electroplating contact seed layer 171 is patterned to provide isolation structures 171A, 171B, 171C and 171D which are provided to electrically isolate electrodes 150 and 160, and electrically isolate electrodes 250 and 260. In addition, passivation openings are formed to subsequently electrically connect electrodes 150 and 250 to metallization layers 130 and 230 for control of the shorter electrode's (150 and 250) bias by the semiconductor control circuit transistor(s) 110 and 230.

With reference to FIG. 4D, metal electroplating is used to 1) fill the cavities 150-Cav and 160A-Cav (shown in FIG. 4C) with electrically conductive material to form the first electrode 150 and lower portion 160A of the second electrode 160, respectively, and 2) fill the cavities 250-Cav and 260A-Cav (shown in FIG. 4C) with electrically conductive material to form the first electrode 250 and lower portion 260A of the second electrode 260, respectively. According to an example embodiment, the electrically conductive material used to form pillars 150, 160A, 250 and 260A may include metals (Cu, Ag, Au, Al) or metal compounds. For example, the electrically conductive material may be copper (Cu), and thus copper electroplating is used. The electroplating fills the cavities 150-Cav, 250-Cav, 160A-Cav, and 260A-Cav, but will also typically extend outside the upper ends of the cavities.

At this stage of the fabrication process, therefore, the top end surfaces of electrode pillars 150, 160A, 250 and 260A may have surface profiles that are unacceptable and may include underfilled HM cavity regions EPTS as shown in FIG. 4D for electrode pillars 150 and 160A, and/or overfilled metal regions EPTS as shown in FIG. 4D for electrode pillar 230, and/or overfilled metal regions EPTS as shown for electrode 260A.

Next, as shown in FIG. 4E, after the metal electroplating process is completed for the first HM layer 181, a CMP process is used to planarize the top surfaces of the HM layer 181 and electrode pillars 150, 160A, 250, and 260A, thereby removing or eliminating the underfilled HM cavity regions EPTS, the overfilled metal regions EPTS, and the overfilled metal regions EPTS as shown fin FIG. 4D.

Referencing FIG. 4F, illustrated are the next steps for forming electrode pillars 160B and 260B. The process is analogous to that just described with reference to FIGS. 4B-4E, and performs a patternable hard mask process to bond, deposit and photo pattern a second hard mask layer 182 on the first hard mask layer 181 and electrode pillar top surfaces of electrodes 150, 160A, 250 and 260A. Alternatively, the patternable hard mask process uses a deposition or coating process to form the hard mask. The second hard mask layer 182 is deposited/coated on or bonded to the first hard mask layer 181. If a bonding process is used, it may include a bonding adhesion layer 172. If 172 acts as an etching stop layer, the etching stop layer material can be metal (Ti, Cu, Al, . . . ), diffusion barrier material (TaN, TiN, . . . ), and/or dielectric material (silicon dioxide, silicon nitride, . . . ).

According to the example embodiment illustrated, the second hard mask layer 182 thickness or height is H2. Again, a dry etching process is used to etch cavities corresponding to the eventual upper portions 160B and 260B of the second electrodes 160 and 260. The cavities have a width of W2 in the second hard mask 182 and are formed aligned at the locations of the corresponding lower pillar portions 160A and 260A. A subsequent metal electroplating process fills the cavities in the second hard mask 182 with an electrically conductive material to form electrode pillars 160B and 260B. Typically (although not necessarily) the same electrically conductive material is used in this second electroplating step as was used in the electroplating step of FIG. 4D. As shown in FIG. 4F, the width W2 of electrode pillars 160B is less than the width W1 of electrode pillar 160A, and the width W2 of electrode pillars 260B is less than the width W1 of electrode pillar 260A. Again, the pillars 260B typically are formed with a circular cross-section, but can instead have a square, hexagonal, or other cross-section. A subsequent CMP or other planarization is performed after the electroplating to planarize the exposed ends of the electroplated upper pillar portions 160B and 260B.

According to an example embodiment, bonding layer 172 material may be a polymer such as a thermoset or photosensitive polymer, including Benzocyclobutene (BCB), or a dielectric, e.g. silicon dioxide.

Referencing FIG. 4G, hard mask layers 181 and 182 are removed using a HM material removal process appropriate for the HM layer material. The resulting hybrid electrode height structure is illustrated in FIG. 4G, which is a duplication of the structure shown in FIG. 4F, except the patterned HM layers 181 and 182 are removed from the structure. As shown in region EPTS of the figure, the top surface of the electrode pillar includes flat electrode end surface profiles and, as referenced by the EPTS area of FIG. 4G, have a side wall profile which is smooth and not jagged i.e. relatively low standard deviation of electrode width.

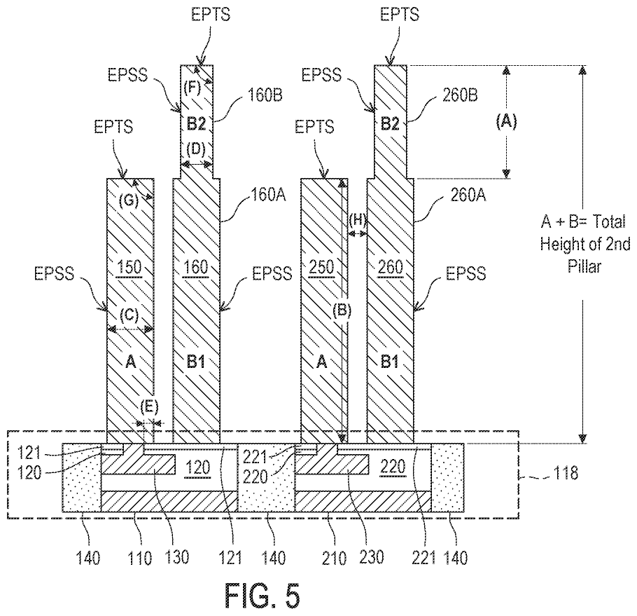

Referencing FIG. 5, illustrated is another view of the electrode structure shown in in FIG. 4G, with added dimensional lines and the following dimension labels:
(A): length/height of electrode pillars 160B and 260B
(B): length/height of electrode pillars 150A and 260A
(C): width of electrode pillars 150, 160A, 250 and 250A
(D):width of electrode pillars 160B and 260B
(E): metal pillar edge to passivation layer opening distance for connection of electrode 150 and 250 to patterned metallization layers 130 and 230, respectively.
(F): top surface inside corner angle for electrode pillars 160B and 260B.
(G): top surface inside corner angle for electrode pillars 150 and 250.
(H): minimum electrode pillar spacing of electrode pillars 150 and 160A, and electrode pillars 250 and 250A.

According to an example embodiment of this disclosure:
A>0;
0<B, or alternatively 0<B<=5 um;
0<C, or alternatively 0<C<0.2 um;
0<D, or alternatively 0<D<0.2 um;
E>0;
F=90+/−5 degrees;
G=90+/−5 degrees;
H<5 um;
(A+B)max−(A+B)min for electrode pillar top surfaces <=5 um;
A/D ratio>4 um/um; B/C ratio>10 um/um; and
C and D sigma (pillar width standard deviation)<0.2 um.
   Furthermore, it should be noted that, in one variant embodiment, the lower portion 160A/260A and the upper portion 160B/260B of the taller electrodes 160/260 may be of equal cross-sectional size or diameter. As another contemplate variant, if both electrodes 150/250 and electrodes 160/260 are to be of the same height, then the second hard mask 182 deposition/patterning and second electroplating steps are suitably omitted.

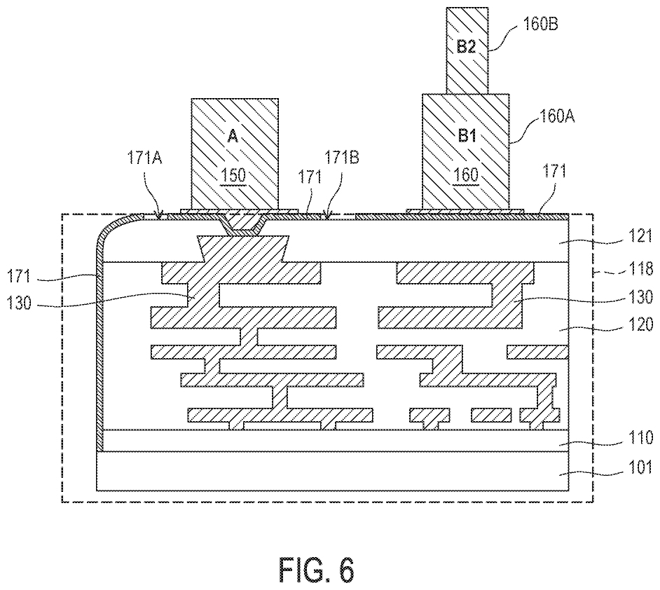

In the illustrative examples thus far, the metallization layer includes only the top metallization (TME). However, the metallization layer can include multiple metallization layers interconnected by via. Such metallization stacks are commonly formed in back end-of-line (BEOL) processing of an IC workflow. Referencing FIG. 6, illustrated is a detail view of an example routing of a metallization layer 130 through an IMD/ILD 120 and passivation layer 121 to electrically connect an electrode CMOS driving semiconductor circuit 100 (fabricated on a Si) to electrode 150. As shown, the second, taller electrode 160A is isolated from the CMOS electrode driving circuit and grounded as indicated in FIG. 2 when operated as an e-beam steering plate. Also shown in FIG. 6 is a more detailed view of the passivation layer 12, including PASS openings on the top surface of metalization layer 130, which were previously described. The metallization layers of the metallization stack of FIG. 6 can be utilized for interconnecting other electronics (not shown), such as circuitry for receiving electrical signals controlling the bias voltages applied to the bias electrodes 150.

The foregoing examples provide the reference electrodes 160, 260 with two sections: the lower sections 160A and 260A, and the upper sections 160B, 260B, with the lower sections having smaller diameter than the upper sections. This configuration, along with the reference electrodes being taller (i.e. higher in height) than the biased electrodes, provide beneficial shielding to reduce interference in a multibeam e-beam writer or maskless lithography device. This can be extended to an illustrative three sections, or more.

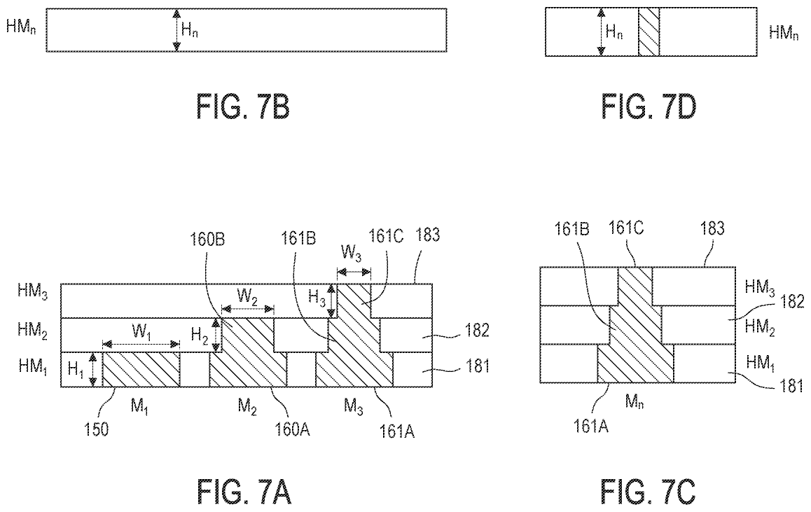

Referencing FIG. 7A-7D, illustrated are additional detail views of a multilayered HM stacking structure, and method of forming the same, to fabricate a series of electrode pillars or other functioning pillars according to this disclosure using a multilayering and HM process as previously described. Specifically, FIG. 7A shows a hard mask layer HMn with a height Hn, as also shown in FIG. 7D with a height Hn, which represents any of the HM1-HMn hard mask layers shown in FIGS. 7A and 7C. FIG. 7A illustrates that multitiered pillars 150, 160A/160B, 161A/161B/161C are formed using a series of patterned HM layers (H_{M1}, H_{M2}, H_{M3} . . . H_{Mn}) 181, 182 and 183 and metal electroplating processes as previously described with reference to FIGS. 4A-4G. Further shown is that each of the formed conductive pillars is interconnected to a separate and distinct patterned metallization layer contact point, i.e. M₁, M₂, M₃ . . . Mₙ. The result is a series of pillars with varying heights (H1, H1+H2, H1+H2+H3, H1+H2+H3+n) and widths (W1, W2, W3, and so on) which can be used as electrodes for semiconductor type devices that require high aspect ratio electrodes. According to an example embodiment, Hₙ=0-100 um, and Wₙ₊₁<=Wₙ, 0-100 μm. Such precision tailoring of the width-as-a-function-of height profile can advantageously enable precise tailoring of the electrostatic field formed by the electrodes.

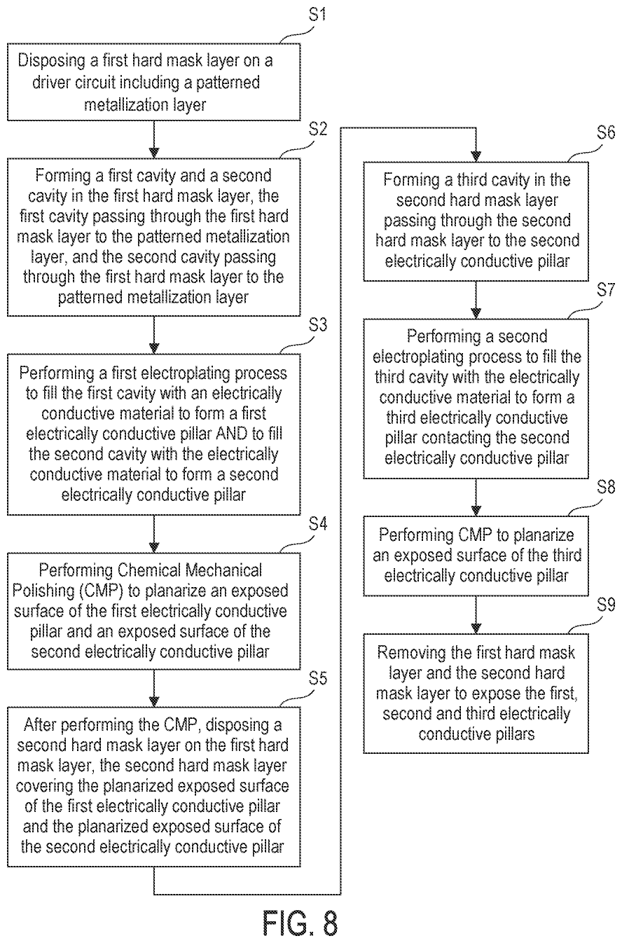

Referencing FIG. 8, shown is a flow chart of an example method of forming an electrode structure for an electron beam steering device according to this disclosure.

At step S1, the method disposes a first hard mask layer on a driver circuit including a patterned metallization layer.

At step S2, the method forms a first cavity and a second cavity in the first hard mask layer, the first cavity passing through the first hard mask layer to the patterned metallization layer, and the second cavity passing through the first hard mask layer to the patterned metallization layer.

At step S3, the method performs a first electroplating process to fill the first cavity with an electrically conductive material to form a first electrically conductive pillar AND to fill the second cavity with the electrically conductive material to form a second electrically conductive pillar.

At step S4, the method performs Chemical Mechanical Polishing (CMP) to planarize an exposed surface of the first electrically conductive pillar and an exposed surface of the second electrically conductive pillar.

At step S5, after performing the CMP, the method disposes a second hard mask layer on the first hard mask layer, the second hard mask layer covering the planarized exposed surface of the first electrically conductive pillar and the planarized exposed surface of the second electrically conductive pillar.

At step S6, the method forms a third cavity in the second hard mask layer passing through the second hard mask layer to the second electrically conductive pillar.

At step S7, the method performs a second electroplating process to fill the third cavity with the electrically conductive material to form a third electrically conductive pillar contacting the second electrically conductive pillar.

At step S8, the method performs CMP to planarize an exposed surface of the third electrically conductive pillar.

At step S9, the method removes the first hard mask layer and the second hard mask layer to expose the first, second and third electrically conductive pillars.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that the electrode structure, and multiple hard mask layering and electroplating method of forming the same, provides improved pillar/electrode profile control, which improves the performance of the electrode structure as it relates to, for example, use with an electron beam steering device.

In the following, some further embodiments are described.

In a nonlimiting illustrative embodiment, a method of forming an electrode structure for an electron beam steering device, the method comprising: disposing a first hard mask layer on a driver circuit including a patterned metallization layer; forming a first cavity and a second cavity in the first hard mask layer, the first cavity passing through the first hard mask layer to the patterned metallization layer, and the second cavity passing through the first hard mask layer to the patterned metallization layer; filling the first cavity and the second cavity with an electrically conductive material to form a first electrically conductive pillar and a second electrically conductive pillar; performing a first planarization process on an exposed surface of the first electrically conductive pillar and an exposed surface of the second electrically conductive pillar; after performing the first planarization process, disposing a second hard mask layer on the first hard mask layer, the second hard mask layer covering the planarized exposed surface of the first electrically conductive pillar and the planarized exposed surface of the second electrically conductive pillar; forming a third cavity in the second hard mask layer passing through the second hard mask layer to the second electrically conductive pillar; filling the third cavity with the electrically conductive material to form a third electrically conductive pillar contacting the second electrically conductive pillar; performing second planarization process on an exposed surface of the third electrically conductive pillar; and removing the first hard mask layer and the second hard mask layer to expose the first, second and third electrically conductive pillars, wherein a first electrode comprises the first electrically conductive pillar, and a second electrode comprises a combination of the second and third electrically conductive pillars.

In another nonlimiting illustrative embodiment, a method of forming an electrode structure for an electron beam steering device, the method comprising: providing a driver circuit including an array of electron beam pass-throughs, driving transistors, and a patterned metallization layer; disposing a first hard mask layer on the driver circuit; forming an array of first cavities passing through the first hard mask layer and an array of second cavities passing through the first hard mask layer, wherein each of a plurality of the electron beam pass-throughs is between one of the first cavities and one of the second cavities; by electroplating, filling the first cavities with an electrically conductive material to form an array of first electrically conductive pillars and the second cavities to form an array of second electrically conductive pillars; planarizing exposed surfaces of the first and second electrically conductive pillars; disposing a second hard mask layer on the first hard mask layer and over the planarized exposed surfaces of the first and second electrically conductive pillars; forming an array of third cavities passing through the second hard mask layer wherein the array of third cavities is aligned with the array of second electrically conductive pillars; by electroplating, filling the third cavities with the electrically conductive material to extend a height of the second electrically conductive pillars; planarizing exposed surfaces of the extended-height second electrically conductive pillars; and removing the first hard mask layer and the second hard mask layer to expose an array of first electrodes consisting of the array of first electrically conductive pillars and an array of second electrodes consisting of the array of extended-height second electrically conductive pillars.

In another nonlimiting illustrative embodiment, an e-beam steering device comprises: a driver circuit including electron beam pass-throughs, driving transistors, and a patterned metallization layer; first electrodes and second electrodes, wherein: the second electrodes have a higher height than the first electrodes, each electron beam pass-through has a first electrode a second electrode on opposite sides of the electron beam pass-through, and the second electrodes have a lower portion proximate to the driver circuit with a first cross-sectional width and an upper portion distal from the driver circuit with a second cross-sectional width that is smaller than the first cross-sectional width.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming an electrode structure for an electron beam steering device, the method comprising:
disposing a first hard mask layer on a driver circuit including a patterned metallization layer;
forming a first cavity and a second cavity in the first hard mask layer, the first cavity passing through the first hard mask layer to the patterned metallization layer, and the second cavity passing through the first hard mask layer to the patterned metallization layer;
filling the first cavity and the second cavity with an electrically conductive material to form a first electrically conductive pillar and a second electrically conductive pillar;
performing a first planarization process on an exposed surface of the first electrically conductive pillar and an exposed surface of the second electrically conductive pillar;
after performing the first planarization process, disposing a second hard mask layer on the first hard mask layer, the second hard mask layer covering the planarized exposed surface of the first electrically conductive pillar and the planarized exposed surface of the second electrically conductive pillar;
forming a third cavity in the second hard mask layer passing through the second hard mask layer to the second electrically conductive pillar;
filling the third cavity with the electrically conductive material to form a third electrically conductive pillar contacting the second electrically conductive pillar;
performing second planarization process on an exposed surface of the third electrically conductive pillar; and
removing the first hard mask layer and the second hard mask layer to expose the first, second and third electrically conductive pillars,
wherein a first electrode comprises the first electrically conductive pillar, and a second electrode comprises a combination of the second and third electrically conductive pillars.

2. The method of claim 1, wherein the third cavity has a smaller cross-sectional width than the second cavity, and the third electrically conductive pillar has a smaller cross-sectional width than the second electrically conductive pillar.

3. The method of claim 1, wherein the driver circuit comprises a silicon substrate and the method further comprises:
forming an electron beam pass-through comprising a through silicon via passing through the silicon substrate,
wherein the first electrode comprises two first electrodes, the second electrode comprises two second electrodes, and the electron beam pass-through is disposed between the two first electrodes and between the two second electrodes.

4. The method of claim 1, wherein the driver circuit includes a transistor that is electrically connected with the first electrode by the patterned metallization layer of the driver circuit.

5. The method of claim 1, wherein
the first and second hard mask layers comprise silicon, a dielectric material and/or polymer; and
the electrically conductive material is Cu, Ag, Al or a compound metal.

6. The method of claim 1, wherein the steps of disposing a second hard mask layer, patterning the second hard mask layer, filling the second hard mask third cavity with an electrically conductive material, and performing a second planarization process are repeatedly performed for a plurality of stacked second hard mask layers to form the third electrically conductive pillar.

7. The method of claim 1, wherein
a first cross-sectional width of the first electrically conductive pillar and the second electrically conductive pillar has a standard deviation of less than 0.2 um;
an angle between a lateral axis of an exposed end surface of the first electrode and a longitudinal axis of the first electrode is 85 to 95 degrees; and
a second cross-sectional width of the third electrically conductive pillar has a standard deviation of less than 0.2 um.

8. The method of claim 1, wherein
a first longitudinal length of the first electrically conductive pillar and the second electrically conductive pillar is 1-100 um;
a first cross-sectional width of the first electrically conductive pillar and the second electrically conductive pillar is 1-100 um;
a second longitudinal length of the third electrically conductive pillar is 1-100 um;
the second cross-sectional width of the third electrically conductive pillar is 1-100 um;
a minimum spacing of the first electrically conductive pillar and the second electrically conductive pillar is less than Sum; and
an aspect ratio is 1-30, the aspect ratio defined as (the first longitudinal length+the second longitudinal length)/the first cross-sectional width.

9. A method of forming an electrode structure for an electron beam steering device, the method comprising:
providing a driver circuit including an array of electron beam pass-throughs, driving transistors, and a patterned metallization layer;
disposing a first hard mask layer on the driver circuit;
forming an array of first cavities passing through the first hard mask layer and an array of second cavities passing through the first hard mask layer, wherein each of a plurality of the electron beam pass-throughs is between one of the first cavities and one of the second cavities;
by electroplating, filling the first cavities with an electrically conductive material to form an array of first electrically conductive pillars and the second cavities to form an array of second electrically conductive pillars;
planarizing exposed surfaces of the first and second electrically conductive pillars;
disposing a second hard mask layer on the first hard mask layer and over the planarized exposed surfaces of the first and second electrically conductive pillars;
forming an array of third cavities passing through the second hard mask layer wherein the array of third cavities is aligned with the array of second electrically conductive pillars;
by electroplating, filling the third cavities with the electrically conductive material to extend a height of the second electrically conductive pillars;
planarizing exposed surfaces of the extended-height second electrically conductive pillars; and
removing the first hard mask layer and the second hard mask layer to expose an array of first electrodes consisting of the array of first electrically conductive pillars and an array of second electrodes consisting of the array of extended-height second electrically conductive pillars.

10. The method of claim 9, wherein the third cavity has a smaller cross-sectional width than the second cavity, and the third electrically conductive pillar has a smaller cross-sectional width than the second electrically conductive pillar.

11. The method of claim 9, wherein the driver circuit comprises a silicon substrate and the method further comprises:
forming an electron beam pass-through comprising a through silicon via passing through the silicon substrate;
wherein the electron beam pass-through is disposed between the two first electrodes and the second electrodes.

12. The method of claim 9, wherein the driving transistors are electrically connected with the first electrodes by the patterned metallization layer.

13. The method of claim 9, wherein
the first and second hard mask layers comprise silicon, a dielectric material and/or polymer; and
the electrically conductive material is Cu, Ag, Al or a compound metal.

14. The method of claim 9, wherein the steps of disposing a second hard mask layer, performing an electroplating process to fill the third cavities, and performing a CMP (Chemical Mechanical Polishing) process are repeatedly performed for a plurality of stacked second hard mask layers to extend the height of the second electrically conductive pillars.

15. The method of claim 9, wherein
a first cross-sectional width of the first electrically conductive pillars and a second cross-sectional width of the second electrically conductive pillars has a standard deviation of less than 0.2 um; and
an angle between a lateral axis of an exposed end surface of the first electrodes and a longitudinal axis of the first electrodes is 85 to 95 degrees.

16. The method of claim 9, wherein
a first longitudinal length of the first electrically conductive pillars and the second electrically conductive pillars is 1-100 um;
a first cross-sectional width of the first electrically conductive pillars and the second electrically conductive pillars is 1-100 um;
a second longitudinal length of the third electrically conductive pillars is 1-100 um;
the second cross-sectional width of the third electrically conductive pillar is 1-100 um;
a minimum spacing of the first electrically conductive pillars and the second electrically conductive pillars is less than 5 μm; and
an aspect ratio is 1-30, the aspect ratio defined as (the first longitudinal length+the second longitudinal length)/the first cross-sectional width.

17. An e-beam steering device comprising:
a driver circuit including electron beam pass-throughs, driving transistors, and a patterned metallization layer;
first electrodes and second electrodes, wherein:
the second electrodes have a higher height than the first electrodes,
each electron beam pass-through has a first electrode a second electrode on opposite sides of the electron beam pass-through, and
the second electrodes have a lower portion proximate to the driver circuit with a first cross-sectional width and an upper portion distal from the driver circuit with a second cross-sectional width that is smaller than the first cross-sectional width.

18. The e-beam steering device of claim 17, wherein
a cross-sectional width of the first electrodes has a standard deviation of less than 0.2 um;
an angle between a lateral axis of an exposed end surface of the first electrodes and a longitudinal axis of the first electrodes is 85 to 95 degrees; and
the first cross-sectional widths of the second electrodes and the second cross-sectional widths of the second electrodes has a standard deviation of less than 0.2 um.

19. The e-beam steering device of claim 17, wherein selectively electrically biasing of the first electrodes deflects an e-beam passing between the first electrodes and the second electrodes.

20. The e-beam steering of claim 17, wherein,
a first longitudinal length of the first electrodes and the second electrode is 1-100 um;
a first cross-sectional width of the first electrodes is 1-100 um;
the first cross-sectional width and the second cross-sectional width of the second electrodes is 1-100 um;
a minimum spacing of the first electrodes and the second electrodes is less than 5 um; and
an aspect ratio is 1-30, the aspect ratio defined as (the first longitudinal length+the second longitudinal length)/the first width.
